(19) United States
(12) Patent Application Publication
(10) Pub. No.: US 2024/0379362 A1
(43) Pub. Date: Nov. 14, 2024

(54) METHOD OF PRODUCING P-TYPE NITRIDE SEMICONDUCTOR

(71) Applicant: SUMITOMO ELECTRIC INDUSTRIES, LTD., Osaka (JP)

(72) Inventors: Kei FUJII, Osaka (JP); Susumu YOSHIMOTO, Osaka (JP); Takeshi AOKI, Osaka (JP); Takuma FUYUKI, Osaka (JP); Suguru ARIKATA, Osaka (JP); Kenshi TAKADA, Osaka (JP)

(73) Assignee: SUMITOMO ELECTRIC INDUSTRIES, LTD., Osaka (JP)

(21) Appl. No.: 18/648,993

(22) Filed: Apr. 29, 2024

(30) Foreign Application Priority Data
May 12, 2023 (JP) 2023-079007

(51) Int. Cl. H01L 21/225; H01L 21/22

(52) U.S. Cl. CPC H01L 21/2258; H01L 21/2225

(57) ABSTRACT

A method of producing a P-type nitride semiconductor includes, in order, applying an SOG solution containing group II atoms on a substrate made of a nitride semiconductor, baking the substrate to form an SOG film, diffusing the group II atoms into the substrate by subjecting the substrate to an annealing treatment under an inert gas atmosphere, and removing the SOG film from the substrate.

### CROSS REFERENCE TO RELATED APPLICATIONS

The present application claims priority based on Japanese Patent Application No. 2023-79007 filed on May 12, 2023, the entire contents of which are incorporated herein by reference.

### TECHNICAL FIELD

The present disclosure relates to a method of producing a P-type nitride semiconductor.

### BACKGROUND

Techniques relating to GaN-based devices such as GaN-based transistors have been disclosed (see, for example, Patent Literature 1, Patent Literature 2, and Non-Patent Literature 1). In the GaN-based transistor disclosed in Patent Literature 1, the semiconductor layer immediately below the gate electrode is formed using a semiconductor material that has a larger band gap than the semiconductor materials used for forming other semiconductor layers.

### CITATION LIST

### Patent Literature

Patent Literature 1: Japanese Patent Application Laid-Open No. 2001-320042

Patent Literature 2: Japanese Patent Application Laid-Open No. 2020-25056

### Non-Patent Literature

Non-Patent Literature 1: H. Sakurai et al., “Highly effective activation of Mg-implanted p-type GaN by ultra-high-pressure annealing”, Appl. Phys. Lett. 115, 142104 (2019)

### SUMMARY

A method of producing a P-type nitride semiconductor according to the present disclosure includes the steps of: applying an SOG solution (Spin on glass) containing group II atoms on a substrate composed of a nitride semiconductor; baking the substrate with the SOG solution containing the group II atoms applied thereon to form an SOG film; diffusing the group II atoms into the substrate by subjecting the substrate with the SOG film formed thereon to an annealing treatment under an inert gas atmosphere; and removing the SOG film from the substrate after the step of diffusing the group II atoms.

### BRIEF DESCRIPTION OF THE DRAWINGS

FIG. 1 is a flowchart illustrating typical steps of a method of producing a P-type nitride semiconductor in Embodiment 1;

FIG. 2 is a schematic cross-sectional view of a prepared substrate;

FIG. 3 is a schematic cross-sectional view illustrating the state in which an insulating film is formed;

FIG. 4 is a schematic cross-sectional view illustrating the state in which a surface of the substrate is partially exposed;

FIG. 5 is a schematic cross-sectional view illustrating the state in which the substrate has undergone a baking step;

FIG. 6 is a schematic cross-sectional view at the time when a group II atom diffusion step is performed;

FIG. 7 is a schematic cross-sectional view illustrating the state in which Mg atoms are diffused into the substrate;

FIG. 8 is a schematic cross-sectional view illustrating the state in which an SOG film and the insulating film have been removed;

FIG. 9 is a schematic cross-sectional view illustrating the state in which a protective film is formed;

FIG. 10 is a schematic cross-sectional view at the time when a Mg atom activation treatment is performed;

FIG. 11 is a schematic cross-sectional view of a part of a transistor, which is an example of a device to which a P-type nitride semiconductor produced using the P-type nitride semiconductor production method in Embodiment 1 is applied; and

FIG. 12 is a flowchart illustrating typical steps of a method of producing a P-type nitride semiconductor in Embodiment 2.

### DESCRIPTION OF THE PREFERRED EMBODIMENTS

In devices utilizing semiconductors, such as power converters, there is a need to reduce the on resistance of transistors from the perspective of achieving higher efficiency. Here, the use of a nitride semiconductor with high breakdown voltage, such as GaN, is advantageous because it can greatly reduce the on resistance. From the perspective of ensuring high withstand voltage and large current flow, vertical transistors, such as MOSFETs and IGBTs, are suitably used. For such vertical transistors, it is necessary to locally form a P-type semiconductor region. When forming a P-type semiconductor region by ion implantation, for example, it is extremely difficult to selectively form a P-type semiconductor region with sufficient concentration.

Therefore, one of the objects is to provide a method of producing a P-type nitride semiconductor capable of efficiently forming a P-type semiconductor region with sufficient concentration.

According to such a P-type nitride semiconductor production method, a P-type semiconductor region with sufficient concentration can be efficiently formed.
(1) A method of producing a P-type nitride semiconductor according to the present disclosure includes the steps of: applying an SOG solution (Spin on glass) containing group II atoms on a substrate composed of a nitride semiconductor; baking the substrate with the SOG solution containing the group II atoms applied thereon to form an SOG film; diffusing the group II atoms into the substrate by subjecting the substrate with the SOG film formed thereon to an annealing treatment under an inert gas atmosphere; and removing the SOG film from the substrate after the step of diffusing the group II atoms.

For forming a P-type semiconductor region in a P-type nitride semiconductor, an ion implantation method, for example, may be used. However, the ion implantation method may damage the crystals constituting the substrate, leading to degradation of the device characteristics. Particularly in the case of locally forming a P-type semiconductor region with sufficient concentration, the crystals may suffer considerable damage, and such damaged crystals may not be sufficiently recovered even by the subsequent annealing treatment. According to the P-type nitride semiconductor production method described above, the SOG solution containing group II atoms is applied and baked to form the SOG film, and then the group II atoms are diffused into the substrate by the annealing treatment, which makes it possible to locally form a P-type semiconductor region with sufficient concentration. In this case, the crystals would not be damaged, and degradation of the device characteristics can be prevented. The P-type semiconductor region is formed by thermal diffusion, which is a relatively simple process. Accordingly, the above-described P-type nitride semiconductor production method is capable of efficiently forming a P-type semiconductor region with sufficient concentration.
(2) Another method of producing a P-type nitride semiconductor according to the present disclosure includes the steps of: forming an insulating film on a substrate composed of a nitride semiconductor; exposing a portion of a surface of the substrate by removing a portion of the insulating film formed on the substrate; applying an SOG solution containing group II atoms on the exposed surface of the substrate and on the insulating film; baking the substrate with the SOG solution containing the group II atoms applied thereon to form an SOG film; diffusing the group II atoms into the substrate by subjecting the substrate with the SOG film formed thereon to an annealing treatment under an inert gas atmosphere; and removing the SOG film from the substrate after the step of diffusing the group II atoms.

According to such a P-type nitride semiconductor production method, the substrate is partially exposed after the formation of an insulating film thereon. Then, a P-type semiconductor region is formed in the exposed region. In this manner, the region other than the exposed region is covered with the insulating film, which greatly reduces the risk of the SOG solution being applied, making it possible to more reliably form a P-type semiconductor region at a desired position.
(3) In (1) or (2) above, the method of producing a P-type nitride semiconductor may further include the step of activating the group II atoms after the step of diffusing the group II atoms. In this manner, the group II atoms can be activated in the formed P-type semiconductor region, so that the P-type nitride semiconductor can be effectively utilized when applied to a device.
(4) In (3) above, the method of producing a P-type nitride semiconductor may further include the step of forming a protective film for suppressing separation of constituent elements of the substrate on the substrate after the step of diffusing the group II atoms and before the step of activating the group II atoms. In this manner, damage to the crystals constituting the substrate caused by the separation of the constituent elements of the substrate from the substrate can be suppressed, thus reducing the risk of degradation in the characteristics of the device to which the P-type nitride semiconductor is applied.
(5) In any of (1) to (4) above, the step of applying the SOG solution containing the group II atoms may include applying the SOG solution containing the group II atoms by spin coating on the substrate. In this manner, the SOG solution can be applied onto the substrate efficiently and uniformly, i.e., while making the difference in thickness in each region as small as possible. Thus, a P-type semiconductor region can be formed with higher precision.
(6) In any of (1) to (5) above, the group II atom may be magnesium (Mg). Such group II atoms are effectively utilized for forming a P-type semiconductor region.
(7) In any of (1) to (6) above, the annealing treatment may be performed at a temperature from 1100° C. to 1300° C. In this manner, the thermal diffusion of the group II atoms into the substrate can be more reliably promoted, thereby ensuring the formation of a P-type semiconductor region.
(8) In any of (1) to (6) above, the insulating film may include at least one of silicon nitride (SiN), silicon dioxide (SiO₂), and silicon oxynitride (SiON). Such materials are suitably used because they are relatively high in strength and can be joined firmly on the substrate composed of a nitride semiconductor.
(9) In any of (1) to (8) above, the step of removing the SOG film from the substrate may include removing the SOG film from the substrate using buffered hydrofluoric acid. In this manner, the SOG film can be more reliably removed from the substrate. Thus, a P-type semiconductor region can be formed with higher precision.
(10) In any of (4) to (9) above, the protective film may include at least one of diamond-like carbon, SiN, SiO₂, and SiON. Such materials are effectively utilized for a protective film for suppressing separation of nitrogen (N) from the substrate.

Embodiments of the method of producing a P-type nitride semiconductor of the present disclosure will be described below with reference to the drawings. In the drawings referenced below, the same or corresponding portions are denoted by the same reference numerals and the description thereof will not be repeated.

### Embodiment 1

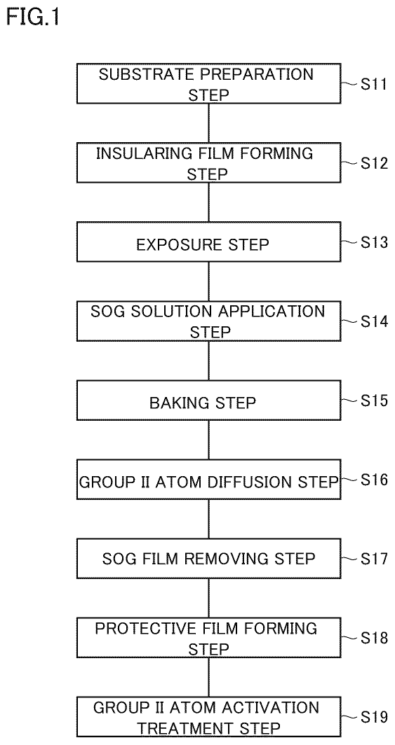

A method of producing a P-type nitride semiconductor in Embodiment 1 of the present disclosure will now be described. FIG. 1 is a flowchart illustrating typical steps of the method of producing a P-type nitride semiconductor in Embodiment 1.

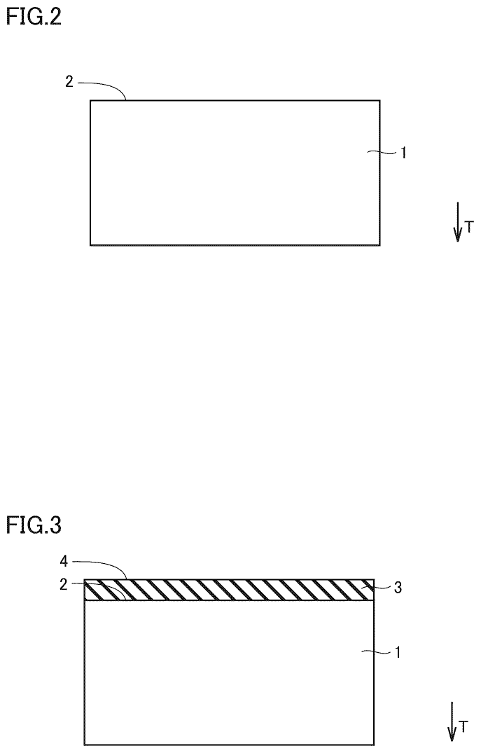

Referring to FIG. 1, in the P-type nitride semiconductor production method in Embodiment 1, a substrate preparation step of preparing a substrate composed of a nitride semiconductor is first performed as step S11. FIG. 2 is a schematic cross-sectional view of a prepared substrate. In FIG. 2 and the drawings referenced below, the direction indicated by the arrow T is a thickness direction of the substrate. Referring to FIG. 2, in this step, a substrate composed of epitaxially grown GaN is prepared as the substrate. In other words, in the present embodiment, gallium nitride (GaN) is selected as the nitride semiconductor. A surface 2 of the substrate 1 in its thickness direction has planarity and cleanliness ensured by performing polishing and cleaning steps.

Next, an insulating film forming step is performed as step S12. FIG. 3 is a schematic cross-sectional view illustrating the state in which an insulating film is formed. Referring to FIG. 3, in this step, the insulating film 3 is formed on the surface 2 of the substrate 1. Specifically, in the present embodiment, the insulating film 3 is formed to cover the entire surface 2 of the substrate 1. With this, a surface 4 of the insulating film 3 is exposed in the substrate 1. The insulating film 3 includes at least one of silicon nitride (SiN), silicon dioxide (SiO₂), and silicon oxynitride (SiON). That is, at least one of SiN, SiO₂, and SiON is selected as the material of the insulating film 3. The surface 4 of the insulating film 3 is flat. The insulating film 3 is formed by, for example, plasma enhanced chemical vapor deposition (PECVD). The insulating film 3 has a thickness selected as appropriate according to the need.

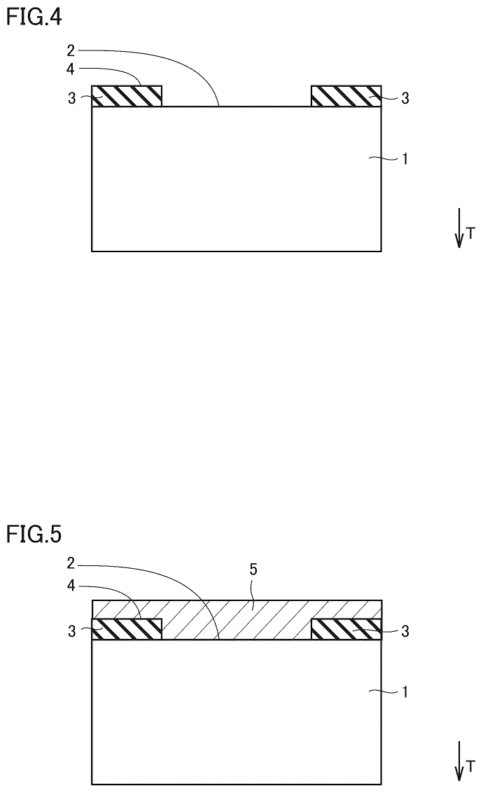

Next, an exposure step is performed as step S13. FIG. 4 is a schematic cross-sectional view illustrating the state in which the surface 2 of the substrate 1 is partially exposed. Referring to FIG. 4, in this step, a portion of the insulating film 3 formed on the surface 2 of the substrate 1 is removed. The region where the insulating film is removed is a region where a P-type semiconductor region is to be formed. Specifically, the substrate 1 having the insulating film 3 formed thereon is patterned using photolithography. Then, dry etching or wet etching is performed on the substrate 1 to remove a portion of the insulating film 3. This exposes a portion of the surface 2 of the substrate 1. Of course, a portion of the insulating film 3 may be removed by other means.

Next, an SOG solution application step is performed as step S14. In this step, an SOG solution containing group II atoms is applied on the substrate 1 with a portion of the surface 2 exposed and the remaining regions covered with the insulating film 3. In the present embodiment, Mg is selected as the group II atom. In other words, the group II atom is magnesium (Mg). Such group II atoms are effectively utilized for forming a P-type semiconductor region.

Here, the SOG solution is applied by spin coating. Specifically, for example, an SOG solution containing Mg is used, and the substrate 1 with a portion of the surface 2 exposed is spun at a main rotational speed of 4000 rpm to cause the substrate to be spin coated with the SOG solution. In this case, the surface 4 of the insulating film 3 and the exposed surface 2 of the substrate 1 are all covered with the SOG solution. It should be noted that the main rotational speed, the time of application, and others are selected as appropriate according to the condition of the SOG solution used, the size of the substrate 1, and the like.

Next, a baking step is performed as step S15. FIG. 5 is a schematic cross-sectional view illustrating the state in which the substrate 1 has undergone the baking step. Referring to FIG. 5, in this step, for example, after the application of the SOG solution by spin coating, baking is carried out using an electric furnace, held at a temperature of 200° C., for 30 minutes. This step is also called a prebake step. With this step, an SOG film 5 is formed on the surface 2 of the substrate 1 and on the surface 4 of the insulating film 3.

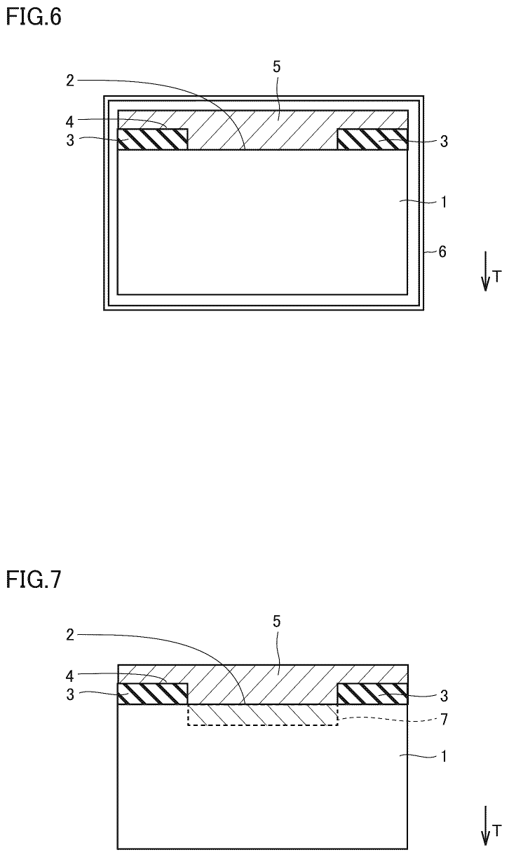

Next, a group II atom diffusion step is performed as step S16. In the present embodiment, a Mg atom diffusion step is performed as the group II atom diffusion step. FIG. 6 is a schematic cross-sectional view at the time when the group II atom diffusion step is performed. Referring to FIG. 6, in this step, an annealing treatment is carried out using an annealing treatment device 6 with an inert gas atmosphere, which is a nitrogen atmosphere in the present embodiment. Specifically, for example, the substrate 1 having the SOG film 5 formed thereon is placed in the annealing treatment device 6, which is used as a thermal diffusion furnace, and the annealing treatment is performed at a temperature from 1100° C. to 1300° C., more specifically at a temperature of 1200°° C., for ten minutes. The time of the annealing treatment may be several tens of minutes. The diffusion of the Mg atoms into the substrate 1 in this case is solid phase diffusion. In this manner, the thermal diffusion of the group II atoms, Mg, into the substrate 1 can be promoted more reliably, thus ensuring the formation of a P-type semiconductor region with sufficient concentration.

In the above-described manner, the Mg atoms are diffused into the substrate 1. FIG. 7 is a schematic cross-sectional view illustrating the state in which the Mg atoms are diffused into the substrate 1. Referring to FIG. 7, in the exposed region of the substrate 1, the Mg atoms are diffused in a region 7, indicated by broken lines, from the surface 2 to the inside. This region 7 with the diffused Mg atoms later forms a P-type semiconductor region.

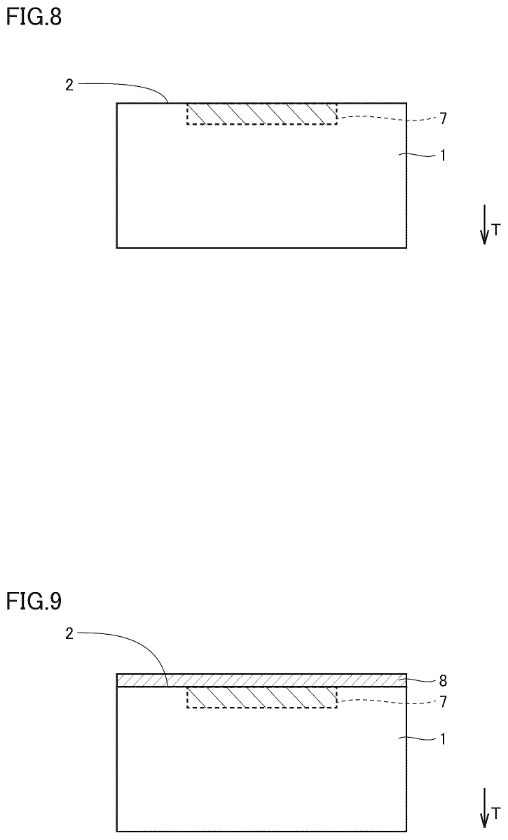

Next, an SOG film removing step is performed as step S17. In this step, for example, buffered hydrofluoric acid (B-HF) is used to remove the SOG film from the surface of the substrate 1. At this time, the insulating film 3 may also be removed together. FIG. 8 is a schematic cross-sectional view illustrating the state in which the SOG film 5 and the insulating film 3 have been removed. Referring to FIG. 8, the substrate 1 has the region 7 formed therein in which the Mg atoms have been diffused from a portion of the surface 2 to the inside.

Next, a protective film forming step is performed as step S18. In this step, for example, diamond-like carbon (DLC) is used for the protective film. The protective film is formed on the substrate 1 to suppress the separation of the constituent elements of the substrate 1, specifically nitrogen (N) in the present embodiment. FIG. 9 is a schematic cross-sectional view illustrating the state in which a protective film is formed. Referring to FIG. 9, the protective film 8 is formed on the surface 2 of the substrate 1 including the region 7 with the Mg atoms diffused therein. The protective film 8 is formed over the entire surface 2 of the substrate 1 including the region 7.

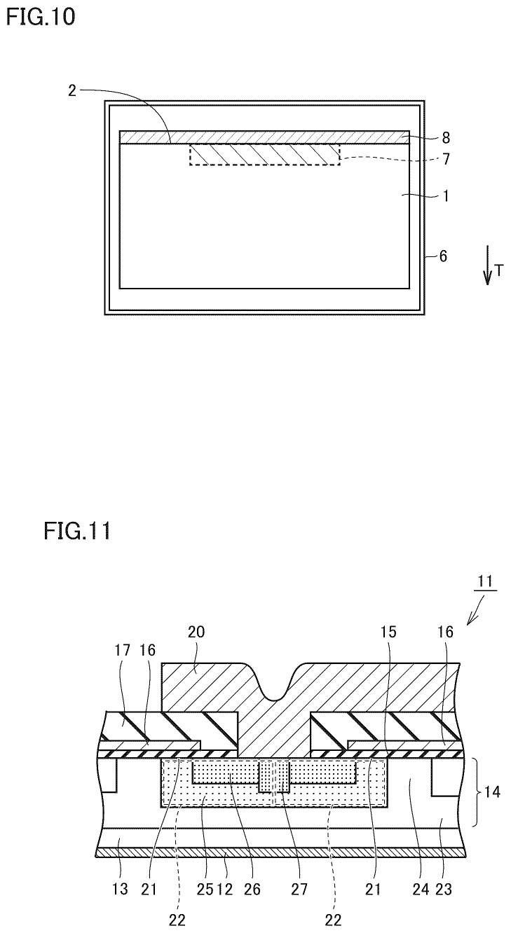

Next, a group II atom activation treatment step is performed as step S19. In the present embodiment, a Mg atom activation treatment step is performed as the group II atom activation treatment step. FIG. 10 is a schematic cross-sectional view at the time when the Mg atom activation treatment is performed. Referring to FIG. 10, in this step, for example, the Mg atoms diffused in the substrate 1 are activated by an annealing treatment. Specifically, as shown in FIG. 10, the substrate 1 having the protective film 8 formed thereon is placed in the annealing treatment device 6. Then, the Mg atom activation treatment is performed at a temperature higher than in the above-described group II atom diffusion step (S16), for example at a temperature of 1400° C. In this manner, the Mg atom activation treatment is conducted to produce a P-type nitride semiconductor.

The P-type nitride semiconductor produced is effectively utilized, for example, in the production of transistors, specifically MOSFETs (metal-oxide-semiconductor field effect transistors) and IGBTs (insulated gate bipolar transistors).

According to such a P-type nitride semiconductor production method, the SOG solution containing Mg atoms is applied and baked to form an SOG film, and then the Mg atoms are diffused into the substrate with an annealing treatment. This allows the local formation of a P-type semiconductor region with sufficient concentration. In this case, the crystals are not damaged, thus preventing degradation of the device characteristics. The P-type semiconductor region is formed by thermal diffusion, which is a relatively simple process. Therefore, according to the P-type nitride semiconductor production method described above, a P-type semiconductor region with sufficient concentration can be formed efficiently.

In the present embodiment, the substrate 1 is partially exposed after the formation of the insulating film 3 thereon. Then, a P-type semiconductor region is to be formed in the exposed region. Thus, the region other than the exposed region is covered with the insulating film 3, which can greatly reduce the risk of the SOG solution being applied, so that a P-type semiconductor region can be formed more reliably at a desired position.

In the present embodiment, the P-type nitride semiconductor production method includes the step of forming the protective film for suppressing the separation of the constituent elements of the substrate on the substrate after the step of diffusing the group II atoms and before the step of activating the group II atoms. Thus, damage to the crystals constituting the substrate due to separation of the constituent elements of the substrate from the substrate can be suppressed, and the risk of degradation in the characteristics of the device to which the P-type nitride semiconductor is applied can be reduced.

It should be noted that while the insulating film is removed together with the SOG film in the SOG film removing step (S17) in the above embodiment, the configuration is not limited thereto. The SOG film alone can be removed, leaving the insulating film, so that the insulating film can be effectively utilized in the subsequent production step(s).

Further, while the protective film is formed in the protective film forming step (S18) in the above embodiment, the configuration is not limited thereto. The protective film may not be formed depending on the need.

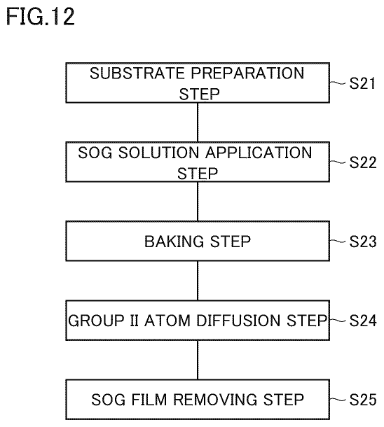

An example of the structure of a device to which a P-type nitride semiconductor produced using the above-described method of producing a P-type nitride semiconductor in Embodiment 1 is applied will now be described in brief. FIG. 11 is a schematic cross-sectional view of a portion of a transistor, which is an example of the device to which a P-type nitride semiconductor produced using the P-type nitride semiconductor production method in Embodiment 1 is applied. FIG. 11 is a cross-sectional view as cut in a plane perpendicular to the thickness direction of the substrate.

Referring to FIG. 11, the transistor 11 includes a drain electrode 12, a GaN substrate 13, a gate insulating film 15, a gate electrode 16, an interlayer insulating film 17, a gate pad (not shown), and a source pad 20. The GaN substrate 13 has a nitride semiconductor 14 formed therein. The transistor 11 of the present embodiment has a planar gate structure. The nitride semiconductor 14 includes an n⁻ drift region 23 arranged on the drain electrode 12 side, and a p⁺ contact region 24 arranged on the gate insulating film 15 side. The nitride semiconductor 14 has a transistor cell 22 in which a p⁻ body region 25, an n⁺ source region 26, and a p⁺ contact region 27 are formed. The p⁻ body region 25 includes a channel region 21.

In the transistor 11, a voltage is applied to the gate electrode 16 to generate an electric field in the channel region 21, to control a current that flows from the source pad 20 through the n⁺ source region 26 and the p⁻ body region 25 of the transistor cell 22 and through the n⁻ drift region 23 to reach the drain electrode 12. The production method of Embodiment 1 above is adopted in the production of the P-type nitride semiconductor in such a transistor 11.

### Embodiment 2

Another embodiment, Embodiment 2, will now be described. FIG. 12 is a flowchart illustrating typical steps of a method of producing a P-type nitride semiconductor in Embodiment 2.

Referring to FIG. 12, the P-type nitride semiconductor production method in Embodiment 2 includes a substrate preparation step (S21) of preparing a substrate composed of a nitride semiconductor, an SOG solution application step (S22) of applying an SOG solution containing Mg atoms as the group II atoms on the prepared substrate, a baking step (S23) of baking the substrate with the SOG solution containing the group II atoms applied thereon to form an SOG film, a group II atom diffusion step (S24) of diffusing the group II atoms into the substrate by subjecting the substrate with the SOG film formed thereon to an annealing treatment under an atmosphere of nitrogen as the inert gas, and an SOG film removing step (S25) of removing the SOG film from the substrate after the step of diffusing the group II atoms. Step S21 corresponds to step S11 in the production method of Embodiment 1. Step S22 corresponds to step S14 in the production method of Embodiment 1. Step S23 corresponds to step S15 in the production method of Embodiment 1. Step S24 corresponds to step S16 in the production method of Embodiment 1. Step S25 corresponds to step S17 in the production method of Embodiment 1. In the present embodiment, the group II atoms are Mg atoms, for example. That is, step S24 is a Mg atom diffusion step.

According to such a P-type nitride semiconductor production method as well, a P-type semiconductor region with sufficient concentration can be formed efficiently.

In Embodiment 2, the group II atom diffusion step (S24) may be performed such that after formation of a resist, the SOG film is patterned with photolithography and the group II atoms are diffused by an annealing treatment. Alternatively, the group II atoms may be diffused over the entire surface by an annealing treatment, and then the SOG film may be removed and the substrate may further be physically scraped for patterning.

In particular, the P-type nitride semiconductor production method in Embodiment 2, includes the group II atom activation treatment step after the SOG film removing step (S25). In particular, the P-type nitride semiconductor production method in Embodiment 2, includes the protective film step after the SOG film removing step (S25) and before the group II atom activation treatment step.

### Other Embodiments

While diamond-like carbon is used for the protective film in the above embodiments, SiN, SiO₂, and SiON, containing N as a part, may be used. The protective film may include at least one of diamond-like carbon, SiN, SiO₂, and SiON. Such materials are effectively utilized for the protective film which suppresses the separation of N from the substrate.

Further, while Mg is used as the group II atom in the above embodiments, not limited thereto, beryllium (Be) or calcium (Ca), for example, may be used as the group II atom. While a nitrogen gas is used as the inert gas, not limited thereto, argon (Ar) or the like may be used as the inert gas.

Furthermore, while the SOG film is removed from the substrate using buffered hydrofluoric acid in the above embodiments, the configuration is not limited thereto. The SOG film may be removed from the substrate by other means, such as hydrofluoric acid. While GaN is used as the nitride semiconductor in the above embodiments, not limited thereto, another nitride semiconductor, such as aluminum nitride (AlN), may be adopted.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

What is claimed is:

1. A method of producing a P-type nitride semiconductor, the method comprising, in order:
applying an SOG solution containing group II atoms on a substrate made of a nitride semiconductor;
baking the substrate to form an SOG film;
diffusing the group II atoms into the substrate by subjecting the substrate to an annealing treatment under an inert gas atmosphere; and
removing the SOG film from the substrate.

2. A method of producing a P-type nitride semiconductor, the method comprising, in order:
forming an insulating film on a substrate made of a nitride semiconductor;
exposing a portion of a surface of the substrate by removing a portion of the insulating film;
applying an SOG solution containing group II atoms on the exposed surface of the substrate and on the insulating film;
baking the substrate to form an SOG film;
diffusing the group II atoms into the substrate by subjecting the substrate to an annealing treatment under an inert gas atmosphere; and
removing the SOG film from the substrate.

3. The method of producing a P-type nitride semiconductor according to claim 1, further comprising activating the group II atoms after the diffusing the group II atoms.

4. The method of producing a P-type nitride semiconductor according to claim 3, further comprising forming a protective film for suppressing separation of constituent elements of the substrate on the substrate after the diffusing the group II atoms and before the activating the group II atoms.

5. The method of producing a P-type nitride semiconductor according to claim 1, wherein the applying the SOG solution includes applying the SOG solution on the substrate by spin coating.

6. The method of producing a P-type nitride semiconductor according to claim 1, wherein the group II atom is Mg.

7. The method of producing a P-type nitride semiconductor according to claim 1, wherein the annealing treatment is performed at a temperature from 1100° C. to 1300° C.

8. The method of producing a P-type nitride semiconductor according to claim 2, wherein the insulating film includes at least one of SiN, SiO₂, and SiON.

9. The method of producing a P-type nitride semiconductor according to claim 1, wherein the removing the SOG film from the substrate includes removing the SOG film from the substrate using buffered hydrofluoric acid.

10. The method of producing a P-type nitride semiconductor according to claim 4, wherein the protective film includes at least one of diamond-like carbon, SiN, SiO₂, and SiON.

11. The method of producing a P-type nitride semiconductor according to claim 2, further comprising activating the group II atoms after the diffusing the group II atoms.

12. The method of producing a P-type nitride semiconductor according to claim 11, further comprising forming a protective film for suppressing separation of constituent elements of the substrate on the substrate after the diffusing the group II atoms and before the activating the group II atoms.

13. The method of producing a P-type nitride semiconductor according to claim 2, wherein the applying the SOG solution includes applying the SOG solution on the substrate by spin coating.

14. The method of producing a P-type nitride semiconductor according to claim 2, wherein the group II atom is Mg.

15. The method of producing a P-type nitride semiconductor according to claim 2, wherein the annealing treatment is performed at a temperature from 1100° C. to 1300° C.

16. The method of producing a P-type nitride semiconductor according to claim 2, wherein the removing the SOG film from the substrate includes removing the SOG film from the substrate using buffered hydrofluoric acid.

17. The method of producing a P-type nitride semiconductor according to claim 12, wherein the protective film includes at least one of diamond-like carbon, SiN, SiO₂, and SiON.

18. The method of producing a P-type nitride semiconductor according to claim 3, wherein the activating the group II atoms is performed at a temperature higher than in the annealing treatment.

19. The method of producing a P-type nitride semiconductor according to claim 11, wherein the activating the group II atoms is performed at a temperature higher than in the annealing treatment.
